(19) United States
(12) Patent Application Publication
(10) Pub. No.: US 2018/0129559 A1
(43) Pub. Date: May 10, 2018

(54) SEMICONDUCTOR MEMORY DEVICE, CONTROLLER, AND OPERATING METHODS THEREOF

(71) Applicant: SK hynix Inc., Gyeonggi-do (KR)

(72) Inventors: Nack Hyun KIM, Gyeonggi-do (KR); Min Kyu PARK, Gyeonggi-do (KR); Min Kyu LEE, Chungcheongbuk-do (KR)

(21) Appl. No.: 15/686,215

(22) Filed: Aug. 25, 2017

(30) Foreign Application Priority Data
Nov. 8, 2016 (KR) 10-2016-0148164
Apr. 11, 2017 (KR) 10-2017-0046895

(51) Int. Cl. G06F 11/10; G11C 29/20; G11C 29/34; G11C 29/02; G11C 29/46; G11C 29/48; G11C 16/06

(52) U.S. Cl. CPC G06F 11/1056; G11C 29/20; G11C 29/34; G11C 2029/1202; G11C 29/46; G11C 29/48; G11C 16/06; G11C 29/025

(57) ABSTRACT

A semiconductor memory device includes a memory cell array, a read/write circuit, a control logic, and a block defect information storage unit. The control logic controls the read/write circuit to perform a read/write operation on the memory cell array. The block defect information storage unit stores information on access records of memory blocks of the memory cell array and whether defects occur in the memory blocks. When the performance of an operation is requested, the control logic controls the read/write circuit to determine whether the memory block is first accessed with reference to the access records of the block defect information storage unit and perform a word line test of the memory block, based on the determination.

### CROSS-REFERENCE TO RELATED APPLICATION

The present application claims priority under 35 U.S.C. § 119(a) to Korean patent application number 10-2016-0148164, filed on Nov. 8, 2016, and Korean patent application number 10-2017-0046895, filed on Apr. 11, 2017, which are herein incorporated by reference in their entirety.

### BACKGROUND

### 1. Field

An aspect of the present disclosure relates to an electronic device, and more particularly, to a semiconductor memory device, a controller, and operating methods thereof.

### 2. Description of Related Art

Memory devices may be formed in a two-dimensional structure in which strings are arranged horizontally to a semiconductor substrate, or be formed in a three-dimensional structure in which strings are arranged vertically to a semiconductor substrate. A three-dimensional semiconductor device is a memory device devised to overcome the limit of degree of integration in two-dimensional semiconductor devices, and may include a plurality of memory cells vertically stacked on a semiconductor substrate.

### SUMMARY

Embodiments provide a semiconductor memory device capable of more efficiently utilizing a memory cell array, and an operating method for the semiconductor memory device.

Embodiments also provide a controller capable of more efficiently utilizing a memory cell array in a semiconductor memory device and an operating method for the controller.

According to an aspect of the present disclosure, there is provided a semiconductor memory device including: a memory cell array having a plurality of memory blocks; a read/write circuit configured to write data to the memory cell array or read data from the memory cell array; a control logic configured to control the read/write circuit to perform a read/write operation on the memory cell array; and a block defect information storage unit configured to store access records of the plurality of memory blocks and information on whether defects occur in the plurality of memory blocks, wherein, when an operation is requested to be performed on any one memory block among the plurality of memory blocks, the control logic determines whether to perform a word line test on the memory block based on the access record, and performs the requested operation on the memory block based on a determination.

According to another aspect of the present disclosure, there is provided an operating method for a semiconductor memory device including a plurality of memory blocks, the operating method including: receiving a command for any one memory block among the plurality of memory blocks; determining whether to perform a defect test on the memory block; performing the defect test based on a determination; and performing an operation corresponding to the received command on the memory block.

According to still another aspect of the present disclosure, there is provided a controller that controls a semiconductor memory device including a memory cell array configured with a plurality of memory blocks and receives a host command and a logic address corresponding thereto from a host, the controller including: a random access memory (RAM) configured to include a map table; an address managing unit configured to convert the logical address into a physical address with reference to the map table; and a test determining unit configured to determine whether the semiconductor memory device is to be tested, based on the physical address.

According to still another aspect of the present disclosure, there is provided an operating method for a controller that controls a semiconductor memory device, the operating method includes: receiving a host command for the semiconductor memory device and a logical address corresponding to the host command; converting the logical address into a physical address; storing the host command in a command queue; determining whether a memory block corresponding to the physical address is to be tested; and outputting a memory command to the semiconductor memory device, based on a determination.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating a semiconductor memory device in accordance with an embodiment of the present disclosure.

FIG. 2 is a block diagram illustrating an embodiment of a block defect information storage unit of FIG. 1.

FIG. 3 is a diagram illustrating a structure of memory cells and word lines, which are included in a memory block.

FIG. 4 is a flowchart illustrating an operating method for a semiconductor memory device in accordance with an embodiment of the present disclosure.

FIG. 5 is a flowchart illustrating in more detail the operating method shown in FIG. 4.

FIG. 6 is a flowchart illustrating an embodiment of the operating method of FIG. 5.

FIGS. 7A to 7C are flowcharts illustrating exemplary embodiments of a step for performing a word line test in the operating method shown in FIG. 6.

FIG. 8 is a block diagram illustrating another embodiment of the block defect information storage unit of FIG. 1.

FIG. 9 is a diagram illustrating a structure of memory cells and word lines, which are included in a memory block.

FIG. 10 is a flowchart illustrating another embodiment of the operating method of FIG. 5.

FIG. 11 is a flowchart illustrating an exemplary embodiment of a step for performing a word line group test, shown in FIG. 10.

FIG. 12 is a flowchart illustrating an exemplary embodiment of a step for determining whether a defective word line is included in a group shown in FIG. 11.

FIG. 13 is a diagram illustrating a structure of memory cells and word lines, which are included in a memory block.

FIG. 14 is a block diagram illustrating a controller, and a host and a semiconductor memory device, which are coupled thereto, in accordance with an embodiment of the present disclosure.

FIG. 15 is a block diagram illustrating an exemplary embodiment of a test determining unit of FIG. 14.

FIG. 16 is a flowchart illustrating an operating method for a controller in accordance with to an embodiment of the present disclosure.

FIG. 17 is a flowchart illustrating in more detail the operating method shown in FIG. 16.

FIG. 18 is a flowchart illustrating in more detail a step for processing a test result, shown in FIG. 17.

FIG. 19 is a block diagram illustrating a memory system including the semiconductor memory device of FIG. 1.

FIG. 20 is a block diagram illustrating an application example of the memory system shown in FIG. 19.

FIG. 21 is a block diagram illustrating a computing system including the memory system described in FIG. 20.

### DETAILED DESCRIPTION

In the following detailed description, only certain exemplary embodiments of the present disclosure have been shown and described, simply by way of illustration. As those skilled in the art would realize, the described embodiments may be modified in variously different ways, all without departing from the spirit or scope of the present disclosure. Accordingly, the drawings and description are to be regarded as illustrative in nature and not restrictive.

In the entire specification, when an element is referred to as being “connected” or “coupled” to another element, it can be directly connected or coupled to the another element or be indirectly connected or coupled to the another element with one or more intervening elements interposed therebetween. In addition, when an element is referred to as “including” a component, this indicates that the element may further include another component instead of excluding another component unless there is different disclosure.

Hereinafter, exemplary embodiments of the present disclosure will be described in detail with reference to the accompanying drawings. The same reference numerals are used to designate the same elements as those shown in other drawings. In the following descriptions, only portions necessary for understanding operations exemplary embodiments may be described, and descriptions of the other portions may be omitted so as to not obscure important concepts of the embodiments.

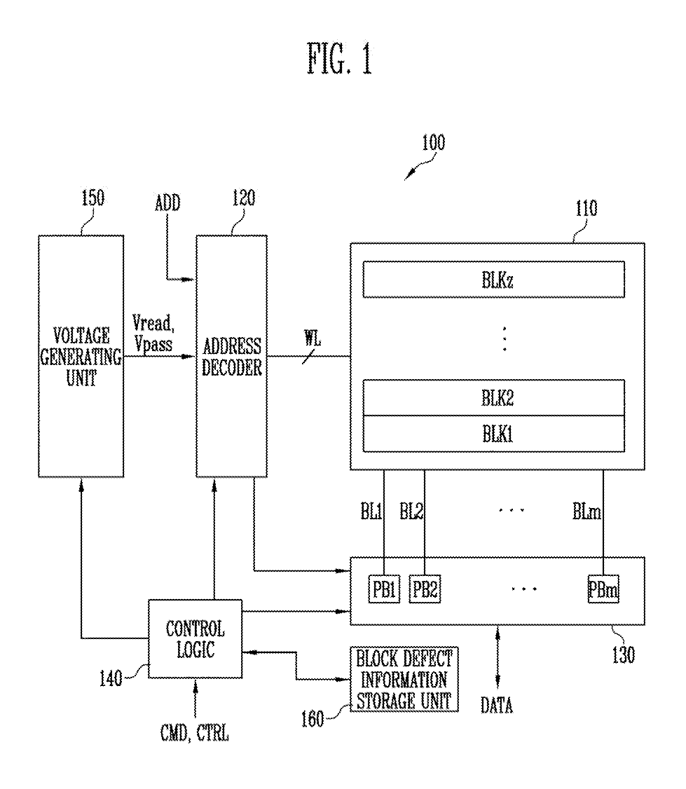

FIG. 1 is a block diagram illustrating a semiconductor memory device 100 according to an embodiment of the present disclosure.

Referring to FIG. 1, the semiconductor memory device 100 includes a memory cell array 110, an address decoder 120, a read/write circuit 130, a control logic 140, a voltage generating unit 150, and a block defect information storage unit 160.

The memory cell array 110 includes a plurality of memory blocks BLK1 to BLKz. The plurality of memory blocks BLK1 to BLKz are coupled to the address decoder 120 through word lines WL. The plurality of memory blocks BLK1 to BLKz are coupled to the read/write circuit 130 through bit lines BL1 to BLm. Each of the plurality of memory blocks BLK1 to BLKz includes a plurality of memory cells. As an embodiment, the plurality of memory cells are nonvolatile memory cells, and may be configured as nonvolatile memory cells having a vertical channel structure. The memory cell array 110 may be configured as a memory cell array having a three-dimensional structure. In some embodiments, the memory cell array 110 may be configured as a memory cell array having a two-dimensional structure. According to an embodiment of the present disclosure, each of the plurality of memory blocks BLK1 to BLKz included in the memory cell array 110 may include a plurality of sub-blocks. As an example, each of the plurality of memory blocks BLK1 to BLKz may include two sub-blocks. As another example, each of the plurality of memory blocks BLK1 to BLKz may include four sub-blocks. In a semiconductor memory device and an operating method thereof according to an embodiment of the present disclosure, the number of sub-blocks included in each memory block is not limited thereto, and various numbers of sub-blocks may be included in each memory block.

Moreover, each of the plurality of memory cells included in the memory cell array 110 may store at least one bit of data. In an embodiment, each of the plurality of memory cells included in the memory cell array 110 may be a single-level cell (SLC) that stores one bit of data. In another embodiment, each of the plurality of memory cells included in the memory cell array 110 may be a multi-level cell (MLC) that stores two bits of data. In still another embodiment, each of the plurality of memory cells included in the memory cell array 110 may be a triple-level cell (TLC) that stores three bits of data. In still another embodiment, each of the plurality of memory cells included in the memory cell array 110 may be a quad-level cell (QLC) that stores four bits of data. In some embodiments, the memory cell array 110 may include a plurality of memory cells that each stores five or more bits of data.

The address decoder 120, the read/write circuit 130, and the control logic 140 operate as peripheral circuits that drive the memory cell array 110. The address decoder 120 is coupled to the memory cell array 110 through the word lines WL. The address decoder 120 is configured to operate in response to control of the control logic 140. The address decoder 120 receives an address ADD through an input/output buffer (not shown) inside the semiconductor memory device 100. The address ADD received includes a block address, a row address, and a column address. The address decoder 120 may include a block decoder, a row decoder, a column decoder, an address buffer, and the like.

The address decoder 120 is configured to decode the block address in the received address to select at least one memory block according to the decoded block address. The address decoder 120 may decode the row address in the received address to select at least one word line of the selected memory block according to the decoded row address. In a read voltage application operation during a read operation, the address decoder 120 applies a read voltage Vread generated by the voltage generating unit 150 to the selected word line and applies a pass voltage Vpass to unselected word lines. In a program verify operation, the address decoder 120 applies a verify voltage generated by the voltage generating unit 150 to the selected word line and applies the pass voltage Vpass to the unselected word lines.

The address decoder 120 is configured to decode the column address in the received address ADD. The address decoder 120 transmits the decoded column address to the read/write circuit 130.

Read and program operations of the semiconductor memory device 100 are performed in units of pages.

The read/write circuit 130 includes a plurality of page buffers PB1 to PBm. The read/write circuit 130 may operate as a “read circuit” in a read operation on the memory cell array 110 and operate as a “write circuit” in a write operation on the memory cell array 110. The plurality of page buffers PB1 to PBm are coupled to the memory cell array 110 through the bit lines BL1 to BLm. In order to sense threshold voltages of memory cells in the read operation and the program operation, the plurality of page buffers PB1 to PBm sense a change in amount of current flowing depending on a program state of a corresponding memory cell while continuously supplying sensing current to bit lines connected to the memory cells and latches the sensed change as sensing data. The read/write circuit 130 operates in response to page buffer control signals output from the control logic 140.

In the read operation, the read/write circuit 130 arbitrarily stores read data by sensing data of a memory cell and then outputs data DATA to the input/output buffer (not shown) of the semiconductor memory device 100. As an exemplary embodiment, the read/write circuit 130 may include a column selection circuit, etc. in addition to the page buffers or page registers.

The control logic 140 is coupled to the address decoder 120, the read/write circuit 130, and the voltage generating unit 150. The control logic 140 receives a command CMD and a control signal CTRL through the input/output buffer (not shown) of the semiconductor memory device 100. The control logic 140 is configured to control overall operations of the semiconductor memory device 100 in response to the control signal CTRL. Also, the control logic 140 outputs the page buffer control signals for controlling sensing node precharge potential levels of the plurality of page buffers PB1 to PBm. The control logic 140 may control the read/write circuit 130 to perform the read operation.

In the read operation, the voltage generating unit 150 generates the read voltage Vread and the pass voltage Vpass in response to a voltage control signal output from the control logic 140.

The block defect information storage unit 160 may store an access record on each of the plurality of memory blocks BLK1 to BLKz in the memory cell array 110. When the control logic 140 is requested to perform an operation on any one of the plurality of memory blocks BLK1 to BLKz, the control logic 140 may search, through the block defect information storage unit 160, an access record that is a record on whether the corresponding memory block was previously accessed. In the semiconductor memory device according to the embodiment of the present disclosure, when the corresponding memory block is first accessed as a result obtained by searching access records stored in the block defect information storage unit 160, the control logic 140 performs a word line test on the memory block and then performs the requested operation.

Therefore, an initial defect test may be performed on every memory block. The defect test is not performed on all memory blocks, but may be performed on only memory blocks on which the requested operation is performed.

In addition, the block defect information storage unit 160 may store, as word line defect information, a result obtained by performing the word line test on each memory block. After the control logic 140 performs the word line test on a memory block, a test result is stored in the block defect information storage unit 160. Accordingly, at least one word line determined as a defective word line is not used in a subsequent operation. In the semiconductor memory device according to the embodiment of the present disclosure, when a defect occurs in a word line of a memory block, the whole of the corresponding memory block is not determined as the defect, but it is determined that only the defective word line is not used. Thus, the storage capacity of the memory cell array 110 can be further increased after the word line test.

In FIG. 1, it is illustrated that the block defect information storage unit 160 is a component implemented separately from the control logic 140. However, the block defect information storage unit 160 may be included in the control logic 140.

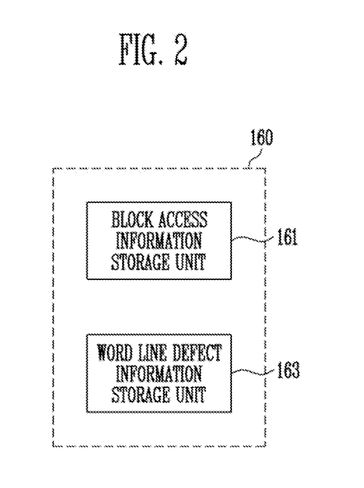

FIG. 2 is a block diagram illustrating an embodiment of the block defect information storage unit 160 of FIG. 1.

Referring to FIG. 2, the block defect information storage unit 160 may include a block access information storage unit 161 and a word line defect information storage unit 163. The block access information storage unit 161 stores an access record of each of the memory blocks BLK1 to BLKz in the memory cell array 110. The word line defect information storage unit 163 stores word line defect information which is a result obtained by performing a word line test on each of the memory blocks BLK1 to BLKz.

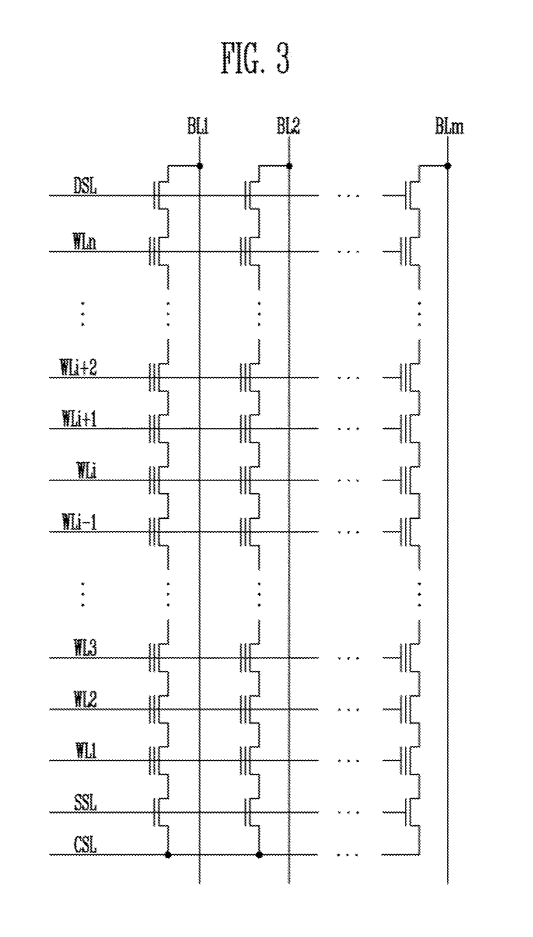

FIG. 3 is a diagram illustrating a structure of memory cells and word lines, which are included in a memory block. In more detail, FIG. 3 is a schematic circuit diagram illustrating one memory block in a memory cell array. The memory block includes m memory cell strings. The memory cell strings are coupled between bit lines BL1 to BLm and a common source line CSL. A drain select transistor and a source select 20) transistor may be respectively coupled to a corresponding one of the bit lines BL1 to BLm, and the common source line CSL, in outermost portions of each memory cell string. A drain select line DSL is coupled to a gate electrode of the drain select transistor, and a source select line SSL is coupled to a gate electrode of the source select transistor. A plurality of memory cells may be coupled between the drain select transistor and the source select transistor. Corresponding word lines WL1, . . . , WLn are coupled to gate electrodes of the memory cells, respectively.

Hereinafter, an operation of the semiconductor memory device according to the embodiment of the present disclosure will be described with reference to FIGS. 2 and 3.

If the control logic 140 receives an operation command for the memory cell array 110, the control logic 140 searches an access record on a corresponding memory block. To this end, access records of the memory blocks, which are stored in the block access information storage unit 161, may be referred. When the corresponding memory block has already been accessed, the control logic 140 does not perform a word line test on the corresponding memory block, but performs the received operation command on the corresponding memory block. When Ss the corresponding memory block has not been accessed, the control logic 140 performs the word line test on the corresponding memory block. In this case, the control logic 140 may perform the word line test on first to nth word lines WL1 to WLn of the corresponding memory block, and control the read/write circuit 130 and the block defect information storage unit 160 to store a result of the word line test in the word line defect information storage unit 163 as word line defect information. In an embodiment, the word line test may be performed through program and verify operations on memory cells. In another embodiment, the word line test may be performed through program and read operations on the memory cells. In an embodiment, the word line test may be performed through an ECC test after the read operation on the memory cells.

After the word line test on the word lines of the corresponding memory block is completed, the received operation command may be performed on the corresponding memory block. In addition, the corresponding memory block has already been accessed, and hence an access record on the corresponding memory block, which is stored in the block access information storage unit 161, is updated.

For example, when it is determined that defects have occurred in a second word line WL2 and an ith word line WLi, word line defect information on the corresponding word lines WL2 and WLi is stored in the word line defect information storage unit 163. Thereafter, when a subsequent operation is performed on the same memory block, the second word line WL2 and the ith word line WLi are not used.

Thus, in the semiconductor memory device according to the embodiment of the present disclosure, when each memory block is first accessed, the word line test is performed on the corresponding memory block. Thereafter, when the same memory block is again accessed, a requested operation can be immediately performed without performing the word line test. Accordingly, a defect test of the semiconductor memory device can be performed during an operation of the semiconductor memory device, without any separate test equipment.

According to the embodiment of FIG. 2, it is illustrated that information on whether each of the memory blocks BLK1 to BLKz in the memory cell array 110 was previously accessed, that is, an access record on each of the memory blocks BLK1 to BLKz in the memory cell array 110, is stored in the block access information storage unit 161 within the block defect information storage unit 160 provided separately from the memory cell array 110. However, in some embodiments, an access record may be stored in a specific memory cell in the corresponding memory block. In this case, when the control logic 140 receives an operation request for the corresponding memory block, the control logic 140 may determine whether the corresponding memory block was previously accessed, with reference to the specific memory cell of the corresponding memory block.

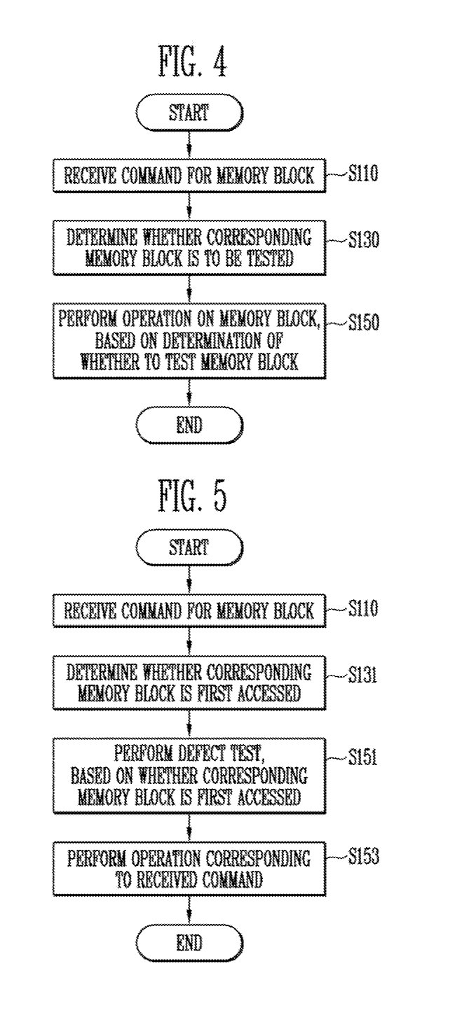

An operating method for the semiconductor memory device in accordance with the embodiment of the present disclosure will be described in detail with reference to FIGS. 4 to 7C.

FIG. 4 is a flowchart illustrating an operating method for a semiconductor memory device in accordance with an embodiment of the present disclosure.

Referring to FIG. 4, the operating method of the semiconductor memory device in accordance with the embodiment of the present disclosure includes a step S110 of receiving a command for any one memory block among a plurality of memory blocks BLK1 to BLKz, a step S130 of determining whether to test the memory block, and a step S150 of performing an operation on the memory block, based on the determination of whether to test the memory block. In step S110, an address corresponding to the command may be received together with the command. In step S130, it is determined whether to test the corresponding memory block, based on the command or the address. As an embodiment, it may be determined whether to test the corresponding memory block, based on whether the corresponding memory block is first accessed. In step S150, only an operation corresponding to the command may be performed, or both a test operation on the memory block and an operation corresponding to the command may be performed, based on the determination of step S130. The operating method for the semiconductor memory device in accordance with the embodiment of the present disclosure will be described in more detail with reference to FIG. 5.

FIG. 5 is a flowchart illustrating in more detail the operating method shown in FIG. 4.

Referring to FIG. 5, the operating method for the semiconductor memory device according to the embodiment of the present disclosure includes a step S110 of receiving a command for any one memory block among a plurality of memory blocks BLK1 to BLKz, a step S131 of determining whether the memory block is first accessed, a step S151 of performing a defect test, based on the determination of whether the memory block is first accessed, and a step S153 of performing an operation corresponding to the received command on the memory block. Since step S110 is identical to step S110 shown in FIG. 4, overlapping descriptions will be omitted.

In the step S131 of determining whether the memory block is first accessed, access records stored in the block access information storage unit 161 within the block defect information storage unit 160 may be referred to. Accordingly, it can be determined whether the corresponding memory block is first accessed or whether the corresponding memory block was previously accessed.

In step S151 of performing the defect test, based on the determination of whether the corresponding memory is first accessed, when the corresponding memory block is first accessed, a word line test may be performed on the corresponding memory block. Whereas, in step S151, when the memory block has already been accessed, the word line test is not performed.

Thereafter, an operation corresponding to the command received in step S110 is performed in step S153.

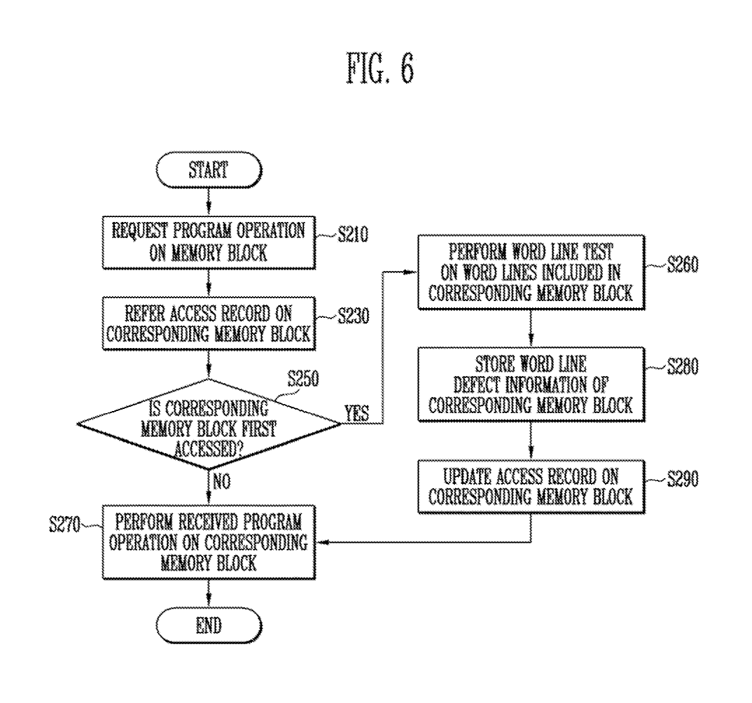

Hereinafter, an exemplary embodiment of the operating method shown in FIG. 5 will be described in detail with reference to FIG. 6.

FIG. 6 is a flowchart illustrating an embodiment of the operating method of FIG. 5. An operating method when a program operation command for a specific memory block in the memory cell array is received is illustrated in FIG. 6.

In step S210, a program operation on a memory block is requested. The request for the program operation may be transmitted as a program command to the semiconductor memory device. In step S230, an access record on the corresponding memory block is referred to. At this time, the access record stored in the block access information storage unit 161 within the block defect information storage unit 160 may be referred to.

In step S250, it is determined whether the corresponding memory block is first accessed, based on the referred access record. When the corresponding memory block has been accessed (“NO” of step S250), a word line test has already been performed on the corresponding memory block. Therefore, an additional word line test is not performed, and the program operation corresponding to the received request is performed in step S270.

When the corresponding memory block is first accessed (“YES” of step S250), a word line test on the corresponding memory block is performed through steps S260, S280, and S290.

That is, in step S260, the word line test is performed on word lines included in the corresponding memory block, for example, the first to nth word lines WL1 to WLn shown in FIG. 3.

In step S280, word line defect information generated as a result of the word line test is stored. For example, when defects occur in the second word line WL2 and the ith word line WLi among the word lines WL1 to WLn shown in FIG. 3, word line defect information notifying that the defects have occurred in the corresponding word lines may be stored in the word line defect information storage unit 163 shown in FIG. 2. When a subsequent operation is performed on the same memory block, the operation on the corresponding memory block may be performed based on the word line defect information. That is, in the subsequent operation, the second word line WL2 and the ith word line WLi may not be used.

In addition to a word line determined as a defective word line, p word lines adjacent to the word line also may not be used. Here, p may be a natural number greater than or equal to 1. For example, in step S260, when a defect occurs in the ith word line, an (i−p)th word line WLi−p to an (i+p)th word line WLi+p may not be used since it is highly likely that defects will occur in word lines located adjacent to a word line determined as a defective word line.

After the word line test is performed, the access record on the corresponding memory block may be updated in step S290. After the access record on the corresponding memory block is updated, the program operation corresponding to the received request is performed in step S270.

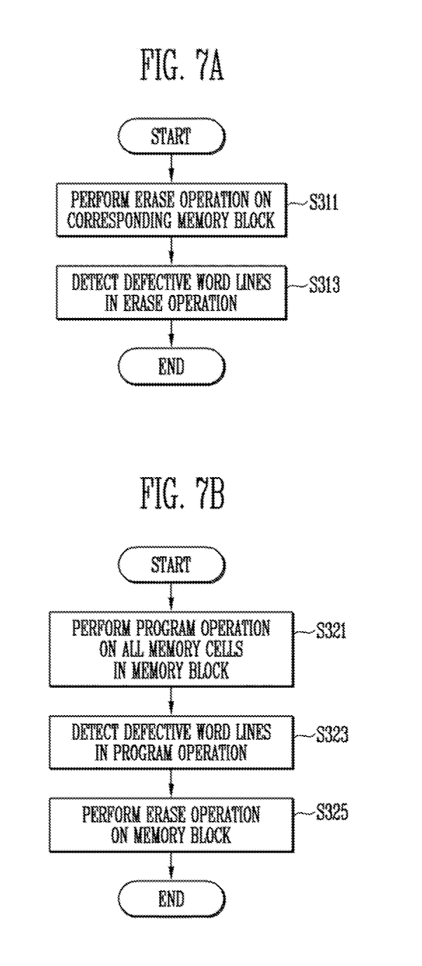

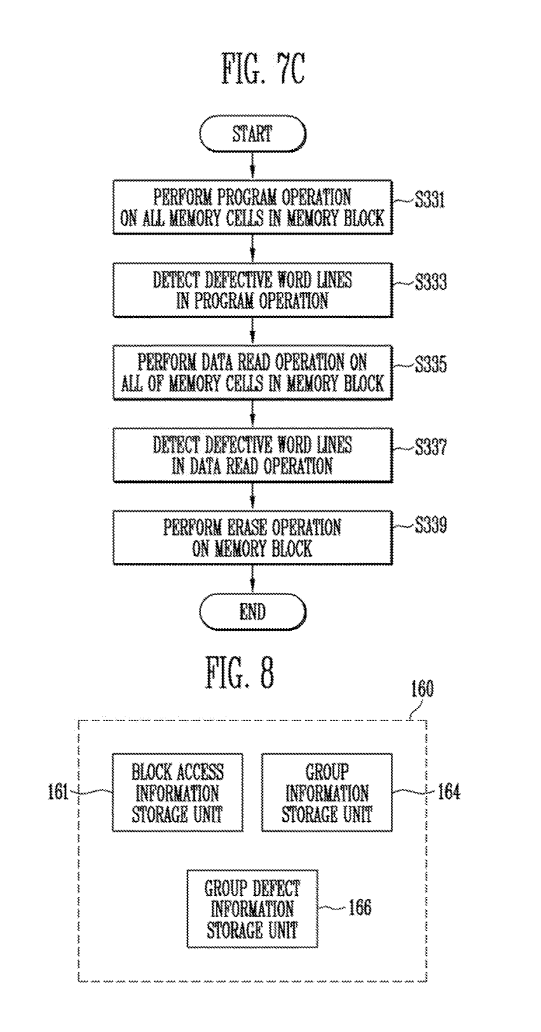

FIGS. 7A to 7C are flowcharts illustrating exemplary embodiments of the step S260 of performing the word line test in the operating method shown in FIG. 6.

First, referring to an embodiment of FIG. 7A, the word line test may be performed through an erase operation on a memory block. In the embodiment shown in FIG. 7A, when a memory block to be accessed is first accessed, an erase operation is performed on the corresponding memory block in step S311.

After the erase operation is performed, word lines in which defects occur in the erase operation may be detected, among all word lines of the corresponding memory block, in step S313. For example, after the erase operation on the corresponding memory block is performed in step S311, defective word lines in the erase operation may be detected through an erase verify operation on memory cells in the memory block.

In another embodiment, referring to FIG. 7B, the word line test may be performed through a program operation on a memory block. In the embodiment shown in FIG. 7B, when a memory block to be accessed is first accessed, a program operation is performed on the corresponding memory block in step S321. The program operation performed in step S321 is separate from the request for the program operation in step S210, and is a program operation for the word line test. Therefore, in the program operation of step S321, dummy data may be written in memory cells within the corresponding memory block.

After the program operation is performed, word lines in which defects occur in the program operation may be detected, among all word lines of the corresponding memory block, in step S323. For example, after the program operation on the corresponding memory block is performed in step S321, defective word lines in the program operation may be detected through a program verify operation on the memory cells in the memory block.

After the defective word line is detected, an erase operation may be performed on the corresponding memory block in step S325. Since the dummy data are programmed to detect the defective word lines in step S321, a subsequent operation may be performed after erasing the corresponding data in step S325. Referring to FIGS. 6 and 7B together, the erase operation is performed on the corresponding memory block in step S325, the word line defect information of the corresponding memory block is stored in step S280, the access record on the corresponding memory block is updated in step S290, and the program operation corresponding to the received request is then performed on the corresponding memory block in step S270.

Referring to FIGS. 7A and 7B, an embodiment in which defective word lines in a memory block are detected through only the erase operation or the program operation is illustrated. However, in some embodiments, defective word lines in a memory block may be detected by combining the ease operation and the program operation. For example, defective word lines in a memory block may be detected by performing the erase operation (S311) and detecting defective word lines in the erase operation (S313) as shown in FIG. 7A, and then performing the program operation (S321), detecting defective word lines in the program operation (S323), and performing the erase operation (S325) as shown in FIG. 7B. In this case, both defective word lines in the erase operation and defective word lines in the program operation may be checked.

Referring to FIG. 7C, in step S331, a program operation may be performed on all memory cells in a memory block. The program operation performed in step S331 is separate from the request for the program operation in step S210, and is a program operation for the word line test. Therefore, in the program operation of step S331, dummy data may be written in the memory cells within the corresponding memory block.

In step S333, word lines in which defects occur in the program operation may be detected. For example, memory cells on which the program operation is not properly performed may be detected through a program verify operation, and word lines corresponding to the detected memory cells may be determined as defective word lines.

In step S335, a data read operation may be performed on all of the memory cells in the memory block. In this case, the dummy data programmed in step S331 may be read.

In step S337, a word line in which defects occur in the data read operation may be detected. As an exemplary embodiment, the data read operation may be performed on the memory cells in the memory block, and memory cells from which data are not properly read may be detected through an ECC test. Thereafter, word lines corresponding to the detected memory cells may be determined as defective word lines.

The defective word lines detected in steps S333 and S337 may be stored in the word line defect information storage unit 163, in step S280 shown in FIG. 6. In addition, an embodiment in which the detection of the defective word lines in the program operation is performed through steps S331 and S333, and the detection of the defective word lines in the data read operation is performed through steps S335 and S337, is illustrated in FIG. 7C. However, in some embodiments, only the detection of the defective word lines in the program operation of steps S331 and S333 may be performed, or only the detection of the defective word lines in the data read operation of steps S335 and S337 may be performed.

After the defective word lines are detected, an erase operation may be performed on the corresponding memory block in step S339. Since the dummy data are programmed to detect the defective word lines in step S331, a subsequent operation may be performed after erasing the corresponding data. Referring to FIGS. 6 and 7C together, the erase operation is performed on the corresponding memory block in step S339, the word line defect information of the corresponding memory block is stored in step S280, the access record on the corresponding memory block is updated in step S290, and the program operation corresponding to the received request is then performed on the corresponding memory block in step S270.

An embodiment in which defective word lines are detected through the program operation and the data read operation is illustrated in FIG. 7C. However, in some embodiments, defective word lines may be detected using all of the erase operation, the program operation, and the data read operation. For example, defective word lines may be detected by performing the erase operation (S311) and detecting defective word lines in the erase operation (S313) as shown in FIG. 7A, and then performing the program operation (S331), detecting defective word lines in the program operation (S333), performing the data read operation (S335), detecting defective word lines in the data read operation (S337), and performing the erase operation (S339) as shown in FIG. 7C.

As described above, in the operating method for the semiconductor memory device according to the embodiment of the present disclosure, the word line test is performed on a memory block that is first accessed, and word line defect information of the corresponding memory block is stored. When defects occur in word lines in the corresponding memory block, the whole of the corresponding memory block is not determined as a defective memory block, but it is determined that only the defective word lines are not used. Thus, the storage capacity of the memory cell array can be further increased after the word line test.

FIG. 8 is a block diagram illustrating another embodiment of the block defect information storage unit 160 of FIG. 1.

Referring to FIG. 8, the block defect information storage unit 160 may include a block access information storage unit 161, a group information storage unit 164, and a group defect information storage unit 166. The block access information storage unit 161 stores an access record of each of the memory blocks BLK1 to BLKz in the memory cell array 110. The group information storage unit 164 stores information for grouping word lines in a memory block into a plurality of word line groups. The group defect information storage unit 166 stores a test result for word line groups of each of the memory blocks BLK1 to BLKz.

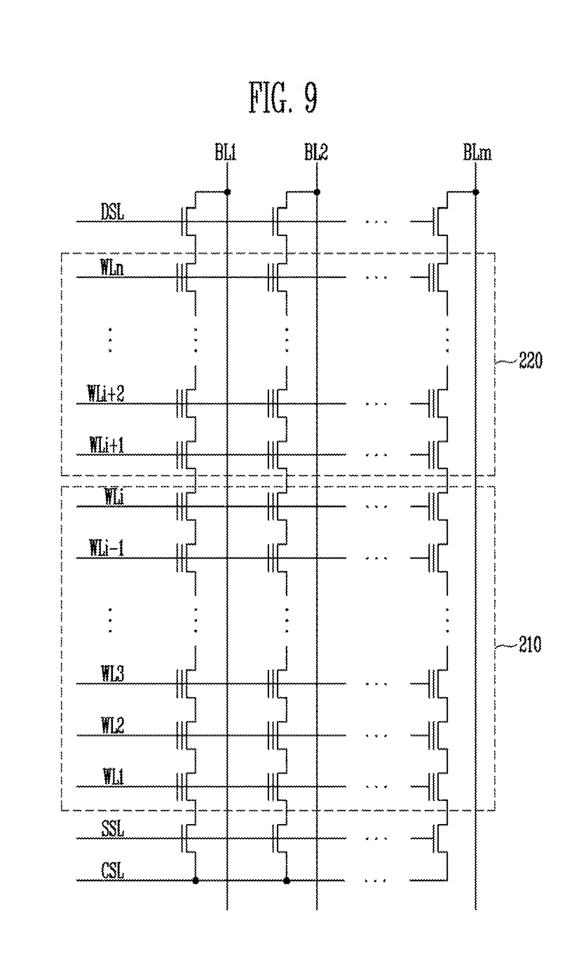

FIG. 9 is a diagram illustrating a structure of memory cells and word lines, which are included in a memory block.

Similarly to FIG. 3, a memory block includes m memory cell strings. The memory cell strings are coupled between bit lines BL1 to BLm and a common source line CSL. A drain select transistor and a source select transistor may be coupled to a corresponding one of the bit lines BL1 to BLm, and the common source line CSL, in outermost portions of each memory cell string. A drain select line DSL is coupled to a gate electrode of the drain select transistor, and a source select line SSL is coupled to a gate electrode of the source select transistor. A plurality of memory cells may be coupled between the drain select transistor and the source select transistor. Corresponding word lines WL1, . . . , WLn are coupled to gate electrodes of the memory cells, respectively.

Moreover, in FIG. 9, the word lines WL1, . . . , WLn in the memory block may be grouped into two word line groups 210 and 220. That is, first to ith word lines WL1 to WLi are included in a first word line group 210, and (i+1)th to nth word lines WLi+1 to WLn are included in a second word line group 220. In addition, information on each word line group and word lines included therein may be stored in the group information storage unit 164. An exemplary embodiment in which the word lines in the memory block are grouped into two word line groups 210 and 220 is illustrated in FIG. 9. However, in some embodiments, the number of word line groups may vary.

Hereinafter, an operation of the semiconductor memory device in accordance with the embodiment of the present disclosure will be described with reference to FIGS. 8 and 9.

If the control logic 140 receives an operation command for the memory cell array 110, the control logic 140 searches an access record on a corresponding memory block. To this end, access records of the memory blocks, which are stored in the block access information storage unit 161, may be referred to. When the corresponding memory block has already been accessed, the control logic 140 does not perform a word line test on the corresponding memory block, but performs the received operation command on the corresponding memory block. When the corresponding memory block has not been accessed, the control logic 140 performs a word line group test on the corresponding memory block. In this case, the control logic 140 may control the read/write circuit 130 and the block defect information storage unit 160 to perform a word line group test on the first word line group 210 and the second word line group 220 and store a test result in the group defect information storage unit 166. In an embodiment, the word line group test may be performed through a word line test on word lines included in a corresponding word line group. The word line test may be performed through program and verify operations on memory cells. In another embodiment, the word line test may be performed through program and read operations on memory cells. In an embodiment, the word line test may be performed through an ECC test after a read operation on the memory cells.

After the word line group test on the word line groups of the corresponding memory block is completed, the received operation command may be performed on the corresponding memory block. In addition, the corresponding memory block has already been accessed, and hence an access record on the corresponding memory block, which is stored in the block access information storage unit 161, is updated.

For example, when it is determined as a test result that a defect has occurred in the first word line group 210, word line group defect information on the first word line group 210 is stored in the group defect information storage unit 166. Thereafter, when a subsequent operation is performed on the same memory block, the first to ith word lines WL1 to WLi included in the first word line group 210 are not used.

Thus, in the semiconductor memory device in accordance with the embodiment of the present disclosure, when each memory block is first accessed, the word line group test is performed on the corresponding memory block. Thereafter, when the same memory block is again accessed, a requested operation can be immediately performed without performing the word line group test. Accordingly, a defect test of the semiconductor memory device can be performed during an operation of the semiconductor memory device, without any separate test equipment.

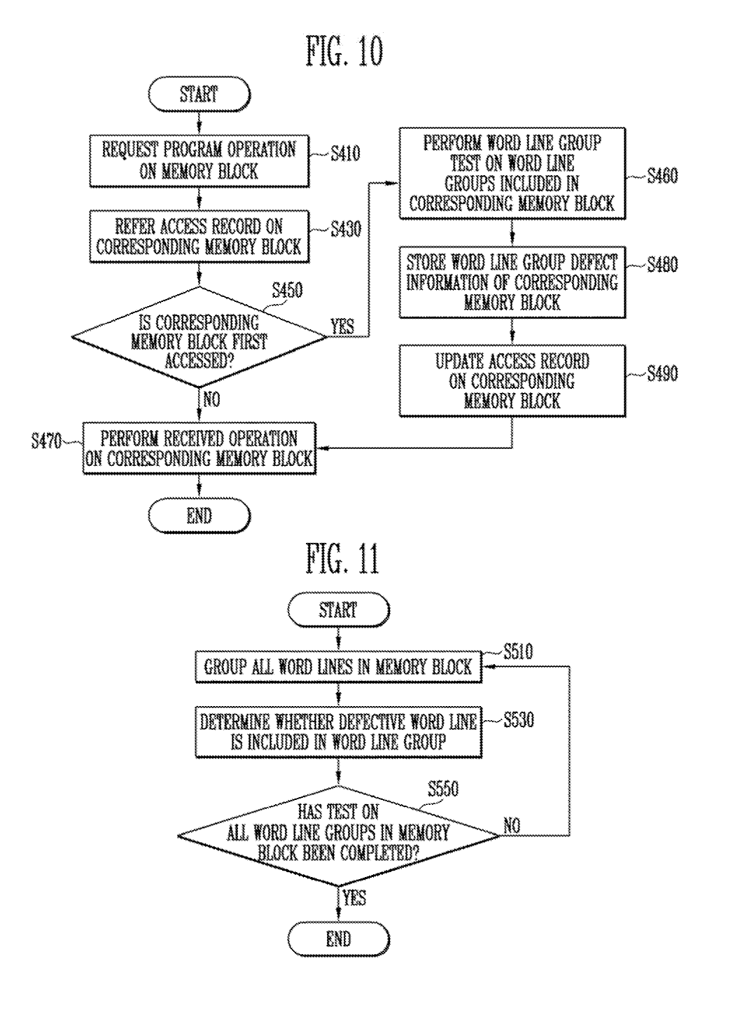

An operating method for the semiconductor memory device in accordance with the embodiment of the present disclosure will be described in detail with reference to FIGS. 10 to 12.

FIG. 10 is a flowchart illustrating another embodiment of the operating method of FIG. 5. An operating method when a program operation command for a specific memory block in the memory cell array is received, is illustrated in FIG. 10.

In step S410, a program operation on a memory block is requested by a program operation command. In step S430, an access record on the corresponding memory block is referred to. At this time, the access record stored in the block access information storage unit 161 within the block defect information storage unit 160 is referred to.

In step S450, it is determined whether the corresponding memory block is first accessed, based on the referred access record. When the corresponding memory block has already been accessed (“NO” of step S450), a word line test has already been performed on the corresponding memory block. Therefore, an additional word line test is not performed, and the program operation corresponding to the received request is performed in step S470.

When the corresponding memory block is first accessed (“YES” of step S450), a word line group test on the corresponding memory block is performed through steps S460, S480, and S490.

That is, in step S460, the word line group test is performed on word line groups included in the corresponding memory block, for example, the first and second word line groups 210 and 220 shown in FIG. 8.

In step S480, word line group defect information generated as a result of the word line group test is stored. For example, when a defect occurs in the first word line group 210 among the word line groups shown in FIG. 8, word line group defect information notifying that the defect has occurred in the corresponding word line group may be stored in the group defect information storage unit 166 shown in FIG. 8. When a subsequent operation is performed on the same memory block, the operation on the corresponding memory block may be performed based on the word line group defect information. That is, in the subsequent operation, the first to ith word lines WL1 to WLi included in the first word line group 210 may not be used.

After the word line group test is performed, the access record on the corresponding memory block may be updated in step S490. After the access record on the corresponding memory block is updated, the program operation corresponding to the received request is performed in step S470.

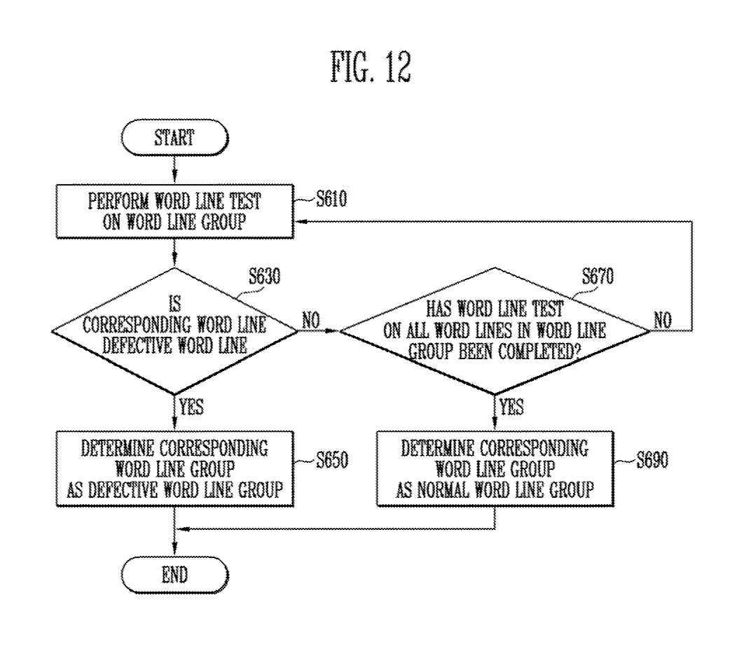

FIG. 11 is a flowchart illustrating an exemplary embodiment of the step S460 for performing the word line group test, shown in FIG. 10.

Referring to FIG. 11, first, all word lines in a memory block are grouped in step S510. In step S510, the number of word line groups into which the word lines in the memory block are to be grouped may be determined. The number of word line groups may be determined based on information stored in the group information storage unit 164 shown in FIG. 8. Also, in step S510, word lines included in each word line group may be determined. The word lines included in each word line group may be determined based on information stored in the group information storage unit 164 shown in FIG. 8. For example, as shown in FIG. 9, word lines in a memory block may be grouped into two word lines 210 and 220, first to ith word lines WL1 to WLi may be included in a first word line group 210, and (i+1)th to nth word lines WLi+1 to WLn may be included in a second word line group 220.

In step S530, it may be determined whether each word line group includes at least one defective word line. In step S550, it is determined whether a test on all word line groups in the memory block has been completed. When the test on all of the word line groups is not completed (“NO” of step S550), steps S510 and S530 are repeated until the test on all of the word line groups in the memory block is performed.

FIG. 12 is a flowchart illustrating an exemplary embodiment of the step S530 of determining whether a defective word line is included in a word line group shown in FIG. 11. Hereinafter, the step of determining whether a defective word line is included in the word line group will be described with reference to FIGS. 9 and 12.

In step S610, a word line test is performed on a word line group in a memory block. For example, the word line test may be performed on the first word line group 210. For example, the word line test may be performed on the first word line WL1.

Thereafter, it is determined whether the corresponding word line is a defective word line in step S630. For example, it may be determined whether the first word line WL1 is a defective word line. When the first word line WL1 is the defective word line (“YES” of step S630), the first word line group 210 is determined as a defective group in step S650.

When the first word line WL1 is not the defective word line (“NO” of step S630), it is determined whether the word line test on all word lines in the first word line group 210 has been completed in step S670. Since the word line test on all of the word lines in the first word line group 210 is not completed (“NO” of step S670), the operating method may proceed to step S610. In this case, the word line test may be performed on the second word line WL2.

By repeating the above-described process, when all of the first to ith word lines WL1 to WLi are determined as normal word lines after the word line test on all of the word lines in the first word line group 210 is completed (“YES” of step S670), the first word line group 210 is determined as a normal word line group (S690).

Referring to FIGS. 11 and 12 together, when at least one defective word line is included in a word line group, the corresponding word line group is determined as a defective word line group. Since information on a defective word line is not stored, and information on a defective word line group is stored, a smaller capacity of the semiconductor memory device can be used to store defect information of a memory block.

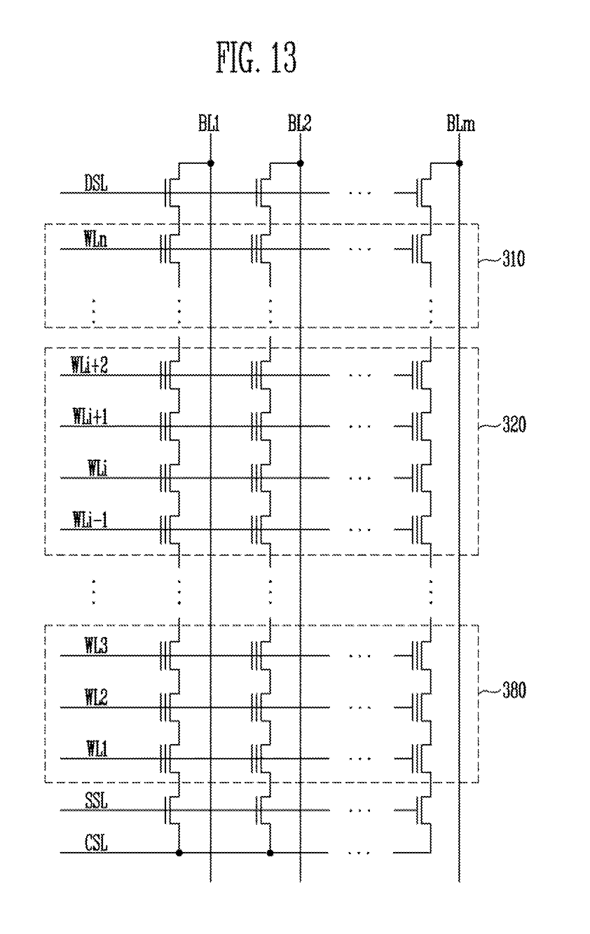

FIG. 13 is a diagram illustrating a structure of memory cells and word lines, which are included in a memory block. FIG. 13 illustrates another embodiment of a case in which word lines in a memory block are grouped.

An embodiment in which word lines in a memory block are grouped into two word line groups is illustrated in FIG. 9. However, an embodiment in which word lines in a memory block are grouped into three or more word line groups 310, 320, . . . , 380 is illustrated in FIG. 13. That is, in the operating method for the semiconductor memory device in accordance with the embodiment of the present disclosure, various number of word line groups may be selected, if necessary. Moreover, numbers of word lines included in word line groups may be equal to or different from one another.

Therefore, the number of word lines determined not to be used due to defects may be changed depending on the number of word line groups.

For example, when a relatively small number of word line groups are used, a relatively large number of word lines are included in one word line group. Therefore, when one word line group is determined as a defective word line group, a larger number of normal word lines are not used so that the number of memory cells available in a memory block is decreased. Thus, the capacity required to store information on defective word line groups is further decreased, but a smaller capacity is required to implement the group defect information storage unit 166.

Conversely, when a relatively large number of word line groups are used, a relatively small number of word lines are included in one word line group. Therefore, when one word line group is determined as a defective word line group, a smaller number of normal word lines are not used so that the number of memory cells available in a memory block is increased. Thus, the capacity required to store information on defective word line groups is further increased, but a larger capacity is required to implement the group defect information storage unit 166.

Therefore, the number of word line groups in a memory block and the number of word lines included in each word line group may be determined by various combinations, if necessary.

In the above, a configuration of the semiconductor memory, in which when a command is received, a test is performed based on an access record of a memory block corresponding to the command, has been described. Furthermore, a controller at the outside of the semiconductor memory device may determine that a test is performed based on an access record of a memory block. Hereinafter, a test of the semiconductor memory device, which is determined by the controller, will be described.

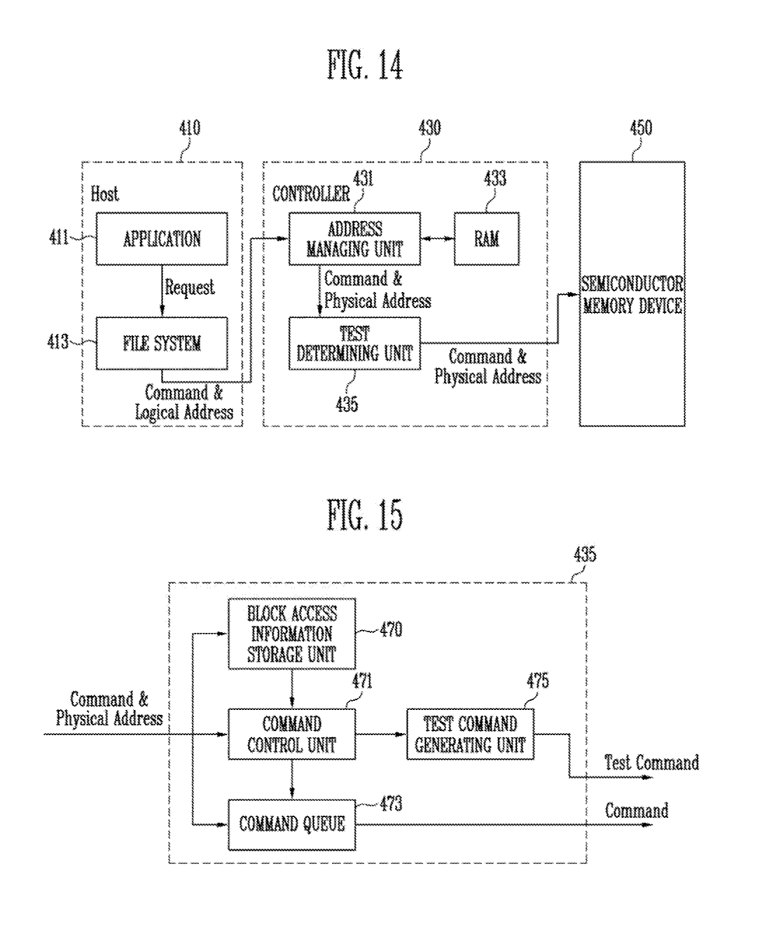

FIG. 14 is a block diagram illustrating a controller 430, and a host 410 and a semiconductor memory device 450, which are coupled thereto, in accordance with an embodiment of the present disclosure.

Referring to FIG. 14, the controller 430 is coupled to the host 410 and the semiconductor memory device 450. The controller 430 is configured to access the semiconductor memory device 450 in response to a request from the host 410. For example, the controller 430 is configured to control read, program, erase, and background operations of the semiconductor memory device 450.

The host 410 may include an application 411 and a file system 413. When there is a need to write data to the semiconductor memory device 450, to read data from the semiconductor memory device 450, or to erase a partial area of the semiconductor memory device 450, the application 411 transmits a corresponding request to the file system 413. The file system 413 transmits a command and a logical address corresponding to the command, to the controller 430, based on the received request. The command output from the host 410 may be referred to as a “host command.”

The controller 430 is configured to provide an interface between the semiconductor memory device 450 and the host 410. The controller 430 is configured to drive firmware for controlling the semiconductor memory device 450. More specifically, the controller 430 may control the semiconductor memory device 450 to perform a corresponding operation by receiving the host command and the logical address from the host 410.

The controller 430 communicates with the semiconductor memory device 450 through a channel. The controller 430 is configured to provide a command and a physical address to the semiconductor memory device 450. The command transmitted to the semiconductor memory device 450 may be referred to as a “memory command.” The physical address is converted from the logical address. According to the memory command and the physical address, the semiconductor memory device may perform read, program, and erase operations. Based on the physical address, the semiconductor memory device 450 may program data in an area corresponding to the physical address, read data from the area corresponding to the physical address, or erase data in the area corresponding to the physical address.

The controller 430 includes an address managing unit 431, a random access memory (RAM) 433, and a test determining unit 435. The RAM 433 includes a mapping table storing a mapping relationship between the logical address received from the host 410 and the physical address provided to the semiconductor memory device 450. The RAM 433 may be controlled by the address managing unit 431. The RAM 433 may include a static RAM (SRAM), a dynamic RAM (DRAM), a synchronous DRAM (SDRAM), and the like. As an embodiment, the RAM 433 may be used as an operation memory of the address managing unit 431. As an embodiment, the RAM 433 may be used as a buffer memory between the semiconductor memory device 450 and the host 410. For example, in a read operation, data read from the semiconductor memory device 450 may be arbitrarily stored in the RAM 433 and be output to the host 410. In a program operation, write data received from the host 410 may be arbitrarily stored in the RAM 433 and be provided to the semiconductor memory device 450.

The address managing unit 431 converts the logical address received from the host 410 into the physical address with reference to the mapping table. Also, the address managing unit 431 manages the mapping table of the RAM 433, to manage a bad area of a memory cell array in the semiconductor memory device 450. For example, the address managing unit 431 does not map a physical address corresponding to the bad area to a logical address, but may map a physical address corresponding to another area substituted for the bad area to the corresponding logical address. In the embodiment of the present disclosure, the address managing unit 431 may be referred to as a “flash translation layer.”

As an embodiment, when a test operation in the semiconductor memory device 450 fails, the address managing unit 431 may detect that a selected word line is a defective word line. In a read operation, the address managing unit 431 may detect that a selected word line is a defective word line through an error correction block (see 1150 of FIG. 19) that may be additionally included in the controller 430.

The address managing unit 431 may process an area including the corresponding word line as a bad area and update the mapping table stored in the RAM 433 such that the area is replaced by another memory area.

The test determining unit 435 may receive a physical address and a host command from the address managing unit 431. The test determining unit 435 may determine whether the semiconductor memory device 450 is to be tested, based on the received physical address. For example, when a memory block corresponding to the received physical address is first accessed, the test determining unit 435 may determine that the semiconductor memory device 450 is to be tested. More specifically, the test determining unit 435 may determine that the corresponding memory block which is first accessed is to be tested.

When it is determined that the corresponding memory block is to be tested, the test determining unit 435 may generate a test command and transmit the test command along with the physical address to the semiconductor memory device 450. The corresponding memory block of the semiconductor memory device 450 is tested based on the received test command and physical address.

In an embodiment, the test command may be an erase command. In this case, which is similarly to that described with reference to FIG. 7A, an erase operation may be performed on the corresponding memory block, and defective word lines in the erase operation may be detected.

In another embodiment, the test command may include a program command and an erase command. In this case, which is similar to that described with reference to FIG. 7B, a program operation may be performed on the corresponding memory block, defective word lines in the program operation may be detected, and an erase operation may be performed on the corresponding memory block.

In still another embodiment, the test command may include a program command, a read command, and an erase command. In this case, which is similar to that described with reference to FIG. 7C, a program operation may be performed on the corresponding memory block, defective word lines in the program operation may be detected, a data read operation may be performed on the corresponding memory block, defective word lines in the data read operation may be detected, and an erase operation may be performed on the corresponding memory block.

After the memory block is tested, the test determining unit 435 may transmit a memory command corresponding to the received host command and a physical address to the semiconductor memory device 450. The semiconductor memory device 450 performs an operation requested from the host 410, based on the received memory command and physical address.

When it is determined that the corresponding memory block is not to be tested, the test determining unit 435 does not generate a test command, but may transmit a memory command corresponding to the received host command and physical address, to the semiconductor memory device 450. In this case, the semiconductor memory device 450 does not perform a test operation but may immediately perform an operation requested from the host 410, based on the received memory command and physical address.

Hereinafter, the configuration and operation of the test determining unit 435 will be described in detail with reference to FIG. 15.

FIG. 15 is a block diagram illustrating an exemplary embodiment of the test determining unit 435 of FIG. 14.

Referring to FIG. 15, the test determining unit 435 may include a block access information storage unit 470, a command control unit 471, a command queue 473, and a test command generating unit 475. The command queue 473 may temporarily store a host command received from the host 410. The block access information storage unit 470 may store access records of a plurality of memory blocks included in the semiconductor memory device 450. For example, the block access information storage unit 470 may store a record on whether each of the plurality of memory blocks included in the semiconductor memory device 450 was previously accessed. The command control unit 471 may determine whether the semiconductor memory device 450 is to be tested, based on an access record of a memory block corresponding to a physical address. More specifically, the command control unit 471 may determine whether word lines of the corresponding memory block are to be tested, based on the access record of the memory block corresponding to the physical address. The test command generating unit 475 may generate a test command for a word line test on the corresponding memory block, based on the determination of the command control unit 471.

In an embodiment, the command control unit 471 determines whether a memory block corresponding to the received physical address is first accessed, based on the access record stored in the block access information storage unit 470. When the memory block corresponding to the physical address is first accessed, the command control unit 471 controls the test command generating unit 475 to generate a test command for a word line test on the corresponding memory block. The test command is transmitted to the semiconductor memory device 450 so as to perform a test operation. In this case, the host command is arbitrarily stored in the command queue 473, and is transmitted to the semiconductor memory device 450 after the test operation is performed. Thus, the semiconductor memory device 450 performs an operation request from the host 410 after the test operation is performed.

When the memory block corresponding to the physical address has already been accessed, a word line test has already been performed. Therefore, the test operation of the semiconductor memory device 450 is not performed. To this end, the test command generating unit 475 is controlled not to generate the test command. Moreover, the host command arbitrarily stored in the command queue 473 is immediately transmitted to the semiconductor memory device 450. Thus, the semiconductor memory device 450 performs the operation requested from the host 410 without performing the test operation.

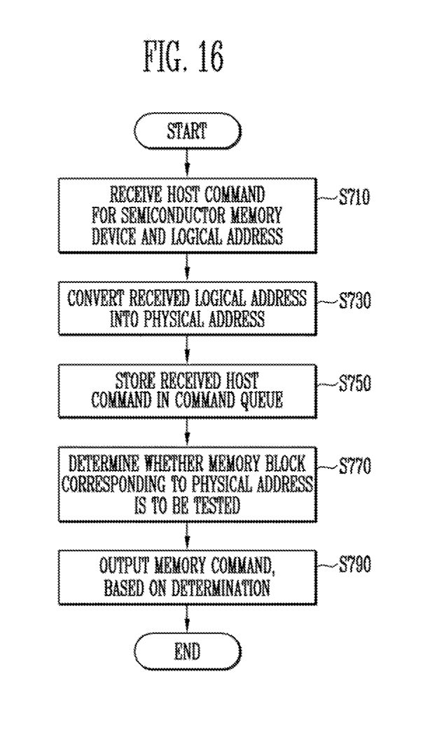

FIG. 16 is a flowchart illustrating an operating method for a controller in accordance with an embodiment of the present disclosure.

Referring to FIG. 16, the controller that controls a semiconductor memory device receives a host command for the semiconductor memory device and a logical address corresponding thereto, from a host, in step S710, converts the logical address into a physical address in step S730, stores the host command in a command queue in step S750, determines whether a memory block corresponding to the physical address is to be tested in step S770, and outputs a memory command to the semiconductor memory device, based on the determination in step S790.

In step S710, the host command and the logical address are transmitted from the host 410 to the controller 430. As described above, the host command may be a command generated by a request of the application 411 in the host 410.

In step S730, the address managing unit 431 may convert the logical address into a physical address. The converted physical address is transmitted to the test determining unit 435. In step S750, the received host command may be stored in the command queue 473 within the test determining unit 435. In FIG. 16, it is illustrated that step S750 is performed after step S730 is performed, but the present disclosure is not limited thereto. For example, in some embodiments, step S730 may be performed after step S750 is performed, or steps S730 and S750 may be simultaneously performed.

In step S770, the test determining unit 435 may determine whether a memory block corresponding to the received physical address is to be tested. More specifically, the command control unit 471 may determine whether a defect test on word lines in the corresponding memory block is to be performed, based on access records stored in the block access information storage unit 470.

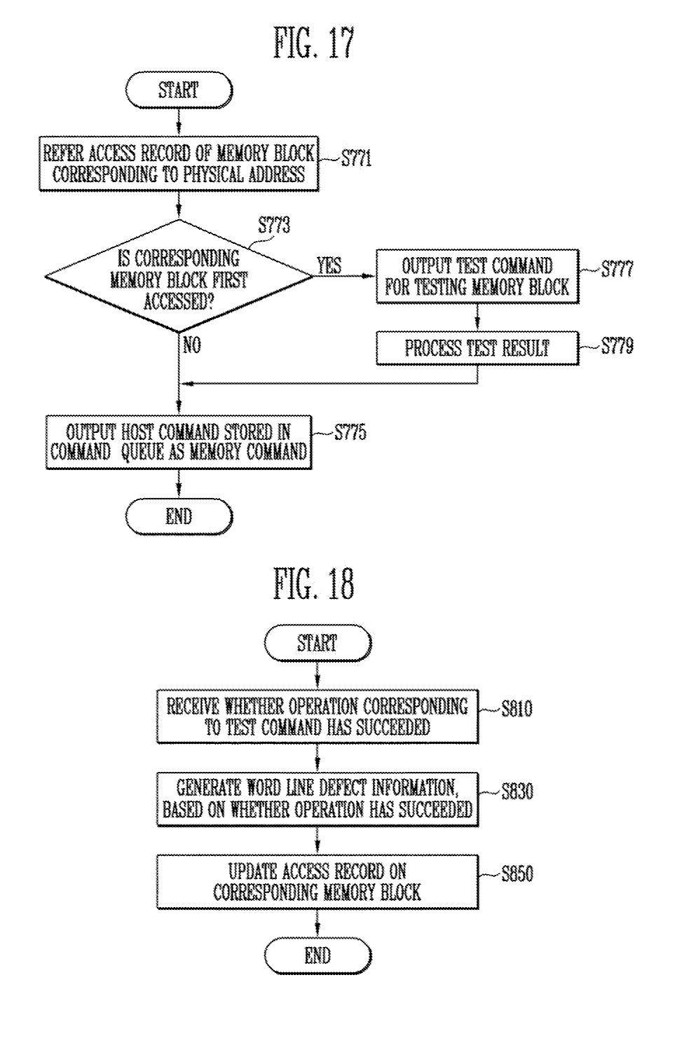

In step S790, the memory command is output based on the determination. When it is determined that the corresponding memory block is to be tested, a test command is first output by the test command generating unit 475, and the host command stored in the command queue 473 is then output. When it is determined that the corresponding memory block is not to be tested, the host command is immediately output without generating the test command. Hereinafter, the operating method of the controller in accordance with the embodiment of the present disclosure will be described in more detail with reference to FIGS. 17 and 18.

FIG. 17 is a flowchart illustrating in more detail the operating method shown in FIG. 16.

Referring to FIG. 17, a specific embodiment of steps S770 and S790 among the steps shown in FIG. 16 is illustrated. That is, step S770 of FIG. 16 includes steps S771 and S773 of FIG. 17. Moreover, step S790 of FIG. 16 includes steps S775, S777, and S779 of FIG. 17.

In step S771, an access record of a memory block corresponding to a physical address stored in the block access information storage unit 470 is referred to. In step S773, it is determined whether the corresponding memory block is first accessed, based on the access record.

When it is determined that the memory block corresponding to the physical address has already been accessed (“NO” of step S773), a host command stored in the command queue 473 is transmitted as a memory command to the semiconductor memory device 450, in step S775. Thus, the semiconductor memory device 450 performs an operation requested by the host 410 without performing a test operation.

When it is determined that the memory block corresponding to the physical address is first accessed (“YES” of step S773), a test command for testing the memory block is output from the test command generating unit 475, in step S777. The semiconductor memory device 450 performs the test operation in response to the test command and transmits a test result to the controller 430. Thereafter, the received test result is processed in step S779. The step S779 of processing the test result will be described in more detail later with reference to FIG. 18. After the test result is processed, the host command stored in the command queue 473 is transmitted as a memory command to the semiconductor memory device 450, in step S775. Thus, the semiconductor memory device 450 performs an operation requested from the host 410 after the test operation is performed.

FIG. 18 is a flowchart illustrating in more detail the step S779 of processing the test result, shown in FIG. 17.

Referring to FIG. 18, the step S779 of processing the test result includes a step S810 of receiving whether an operation corresponding to the test command has succeeded, a step S830 of generating word line defect information, based on whether the operation has succeeded, and a step S850 of updating an access record on the corresponding memory block.

In step S810, whether an operation corresponding to the test command has succeeded is transmitted from the semiconductor memory device 450 to the controller 430. As an example, when the test command is an erase command, it is transmitted whether an erase operation has been satisfactorily completed by the corresponding erase command. As another example, when the test command is a program command, it is transmitted whether a program operation has been satisfactorily completed by the corresponding program command. As still another example, when the test command includes a program command and a data read command, it is determined whether a program operation and a data read operation have been satisfactorily completed by the corresponding commands.

In step S830, word line defect information is generated based on whether the operation has succeeded. When the operation corresponding to the test command is satisfactorily completed, information that corresponding word lines are satisfactory is generated. When the operation corresponding to the test command is not satisfactorily completed, information that corresponding word lines are defective is generated. The mapping table of the RAM 433 may be updated based on the word line defect information. For example, the address managing unit 431 does not map a physical address corresponding to a word line determined as a defective word line to a logical address, but may map a physical address indicating another area to the corresponding logical address.

In step S850, the access record on the corresponding memory block is updated. Since the corresponding memory block becomes a memory block that has already been accessed, the access record stored in the block access information storage unit 470 is updated.

FIG. 19 is a block diagram illustrating a memory system 1000 including the semiconductor memory device 100 of FIG. 1.

Referring to FIG. 19, the memory system 1000 includes a semiconductor memory device 100 and a controller 1100. The semiconductor memory device 100 may be the semiconductor memory device described with reference to FIG. 1. Hereinafter, overlapping descriptions will be omitted.

The controller 1100 is coupled to a host Host and the semiconductor memory device 100. The controller 1100 is configured to access the semiconductor memory device 100 in response to a request from the host Host. For example, the controller 1100 is configured to control read, write, erase, and background operations of the semiconductor memory device 100. The controller 1100 is configured to provide an interface between the semiconductor memory device 100 and the host Host. The controller 1100 is configured to drive firmware for controlling the semiconductor memory device 100.

The controller 1100 includes a random access memory (RAM) 1110, a processing unit 1120, a host interface 1130, a memory interface 1140, and an error correction block 1150. The RAM 1110 is used as at least one of an operation memory of the processing unit 1120, a cache memory between the semiconductor memory device 100 and the host Host, and a buffer memory between the semiconductor memory device 100 and the host Host. The processing unit 1120 controls overall operations of the controller 1100. Also, the controller 1100 may arbitrarily store program data provided from the host Host in a write operation.

The host interface 1130 includes a protocol for exchanging data between the host Host and the controller 1100. As an exemplary embodiment, the controller 1100 is configured to communicate with the host Host through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, and a private protocol.

The memory interface 1140 interfaces with the semiconductor memory device 100. For example, the memory interface 1140 may include a NAND interface or a NOR interface.

The error correction block 1150 is configured to detect and correct an error of data received from the semiconductor memory device 100 by using an error correction code (ECC). The processing unit 1120 may control the semiconductor memory device 100 to adjust a read voltage, based on an error detection result of the error correction block 1150, and to perform re-reading. As an exemplary embodiment, the error correction block 1150 may be provided as a component of the controller 1100.

The controller 1100 and the semiconductor memory device 100 may be integrated into one semiconductor device. As an exemplary embodiment, the controller 1100 and the semiconductor memory device 100 may be integrated into one semiconductor device, to constitute a memory card. For example, the controller 1100 and the semiconductor memory device 100 may be integrated into one semiconductor device, to constitute a memory card such as a PC card (personal computer memory card international association (PCMCIA)), a compact flash (CF) card, a smart media card (SM or SMC), a memory stick, a multimedia card (MMC, RS-MMC or MMCmicro), an SD card (SD, miniSD, microSD or SDHC), or a universal flash storage (UFS).

The controller 1100 and the semiconductor memory device 100 may be integrated into one semiconductor device to constitute a semiconductor drive solid state drive (SSD). The semiconductor drive SSD includes a storage device configured to store data in a semiconductor memory. If the memory system 1000 is used as the semiconductor drive SSD, the operating speed of the host Host coupled to the memory system 1000 can be remarkably improved.

As another example, the memory system 1000 may be provided as one of various components of an electronic device such as a computer, a ultra mobile PC (UMPC), a workstation, a net-book, a personal digital assistant (PDA), a portable computer, a web tablet, a wireless phone, a mobile phone, a smart phone, an e-book, a portable multimedia player (PMP), a portable game console, a navigation system, a black box, a digital camera, a 3-dimensional television, a digital audio recorder, a digital audio player, a digital picture recorder, a digital picture player, a digital video recorder, a digital video player, a device capable of transmitting/receiving information in a wireless environment, one of various electronic devices that constitute a home network, one of various electronic devices that constitute a computer network, one of various electronic devices that constitute a telematics network, an RFID device, or one of various components that constitute a computing system.

As an exemplary embodiment, the semiconductor memory device 100 or the memory system 1000 may be packaged in various forms. For example, the semiconductor memory device 100 or the memory system 1000 may be packaged in a manner such as package on package (PoP), ball grid arrays (BGAs), chip scale packages (CSPs), plastic leaded chip carrier (PLCC), plastic dual in-line package (PDIP), die in Waffle pack, die in wafer form, chip on board (COB), ceramic dual in-line package (CERDIP), plastic metric quad flat pack (MQFP), thin quad flat pack (TQFP), small outline integrated circuit (SOIC), shrink small out line package (SSOP), thin small outline package (TSOP), thin quad flat pack (TQFP), system in package (SIP), multi chip package (MCP), wafer-level fabricated package (WFP), or wafer-level processed stack package (WSP).

In addition, the controller 1100 may be the controller 430 described with reference to FIG. 14. In this case, it may be determined by the controller 430 whether a test is to be performed on the semiconductor memory device 100.

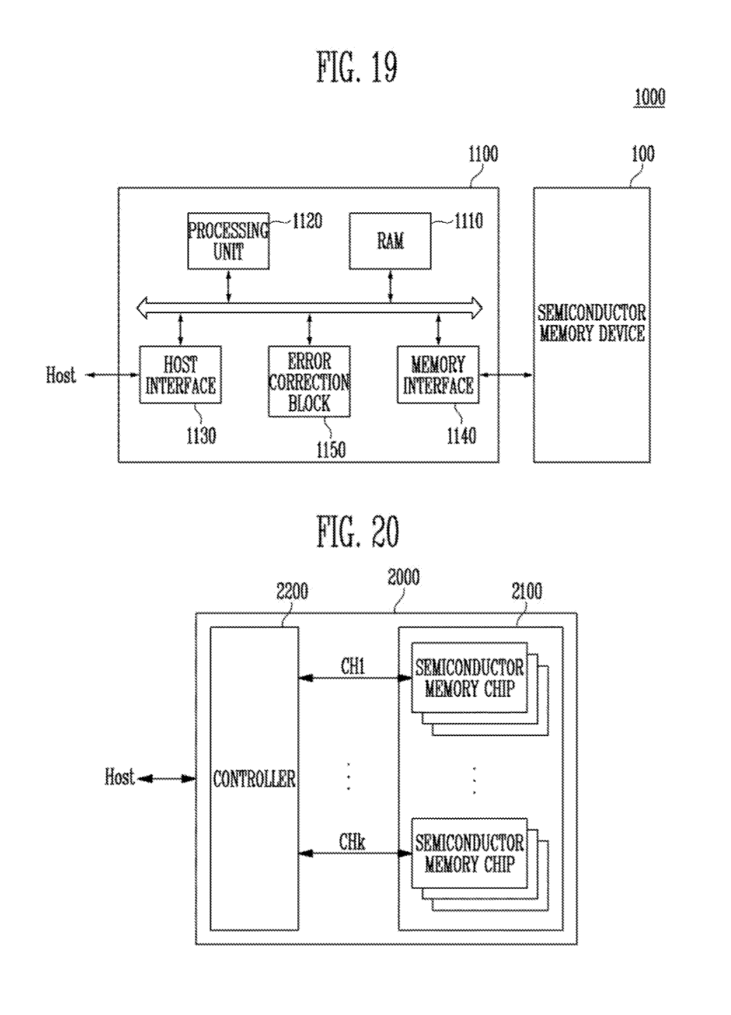

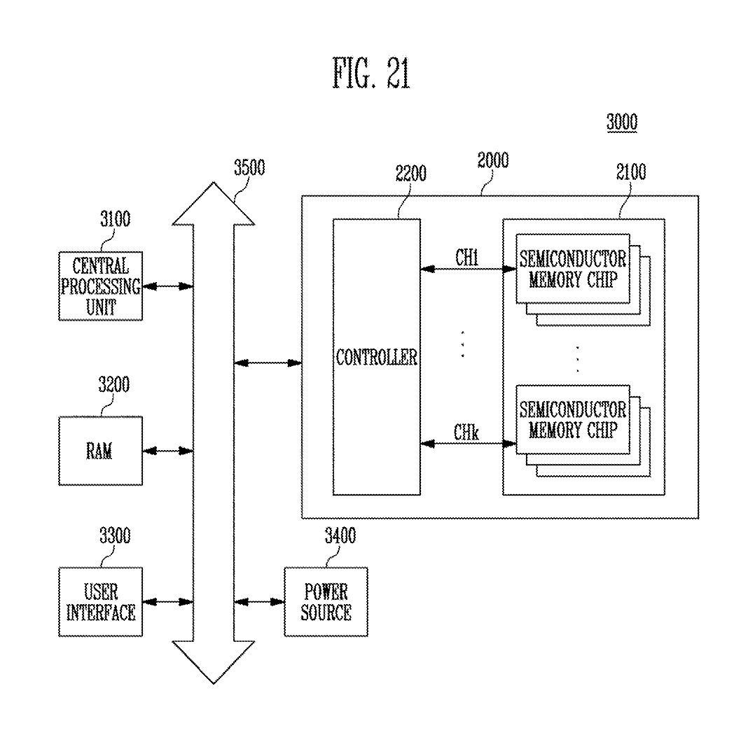

FIG. 20 is a block diagram illustrating an application example of the memory system of FIG. 19.

Referring to FIG. 20, the memory system 2000 includes a semiconductor memory device 2100 and a controller 2200. The semiconductor memory device 2100 includes a plurality of semiconductor memory chips. The plurality of semiconductor memory chips are divided into a plurality of groups.

In FIG. 20, it is illustrated that the plurality of groups communicate with the controller 2200 through first to kth channels CH1 to CHk. Each semiconductor memory chip may be configured and operated identically to the semiconductor memory device 100 described with reference to FIG. 1.

Each group is configured to communicate with the controller 2200 through one common channel. The controller 2200 is configured similarly to the controller 1100 described with reference to FIG. 19. The controller 2200 is configured to control the plurality of memory chips of the semiconductor memory device 2100 through the plurality of channels CH1 to CHk.

FIG. 21 is a block diagram illustrating a computing system 3000 including the memory system 2000 described with reference to FIG. 20.

Referring to FIG. 21, the computing system 3000 includes a central processing unit 3100, a RAM 3200, a user interface 3300, a power source 3400, a system bus 3500, and a memory system 2000.

The memory system 2000 is electrically coupled to the central processing unit 3100, the RAM 3200, the user interface 3300, and the power source 3400 through the system bus 3500. Data supplied through user interface 3300 or data processed by the central processing unit 3100 are stored in the memory system 2000.

In FIG. 21, it is illustrated that the semiconductor memory device 2100 is coupled to the system bus 3500 through the controller 2200. However, the semiconductor memory device 2100 may be directly coupled to the system bus 3500. In this case, the function of the controller 2200 may be performed by the central processing unit 3100 and the RAM 3200.

In FIG. 21, it is illustrated that the memory system 2000 described with reference to FIG. 20 is provided. However, the memory system 2000 may be replaced by the memory system 1000 described with reference to FIG. 19. As an exemplary embodiment, the computing system 3000 may be configured to include both the memory systems 1000 and 2000 described with reference to FIGS. 19 and 20.

According to the present disclosure, it is possible to provide a semiconductor memory device capable of more efficiently utilizing a memory cell array, and an operating method for the semiconductor memory device.

According to the present disclosure, it is possible to provide a controller capable of more efficiently utilizing a memory cell array in a semiconductor memory device and an operating method for the controller.

Example embodiments have been disclosed herein, and although specific terms are employed, the terms are used and are to be interpreted in a generic and descriptive sense only and not for purposes of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A semiconductor memory device comprising:
a memory cell array including a plurality of memory blocks;
a read/write circuit configured to write data to the memory cell array or read data from the memory cell array;
a control logic configured to control the read/write circuit to perform a read/write operation on the memory cell array; and
a block defect information storage unit configured to store access records of the plurality of memory blocks and information on whether defects occurred in the plurality of memory blocks,
wherein, when an operation is requested to be performed on any one memory block among the plurality of memory blocks, the control logic determines whether to perform a word line test on the memory block based on the access records, and performs the requested operation on the memory block based on a determination.

2. The semiconductor memory device of claim 1, wherein the block defect information storage unit includes:
a block access information storage unit configured to store the access records of the plurality of memory blocks; and
a word line defect information storage unit configured to store word line defect information based on a result of the word line test.

3. The semiconductor memory device of claim 2, wherein, when the memory block is first accessed, the control logic controls the read/write circuit to perform the word line test on at least one word line in the memory block, store a result of the word line test of the memory block as the word line defect information in the word line defect information storage unit, update an access record on the memory block, and perform the requested operation on the memory block.

4. The semiconductor memory device of claim 2, wherein, when the memory block has already been accessed, the control logic controls the read/write circuit to perform the requested operation on the memory block without performing the word line test.

5. The semiconductor memory device of claim 1, wherein the block defect information storage unit includes:
a block access information storage unit configured to store the access records of the plurality of memory blocks;
a group information storage unit configured to store group information for grouping word lines in the plurality of memory blocks into a plurality of word line groups; and
a group defect information storage unit configured to store group defect information, based on a result of the word line test on the word line groups of each of the plurality of memory blocks.

6. The semiconductor memory device of claim 5, wherein, when the memory block is first accessed, the control logic controls the read/write circuit to perform the word line test on at least one word line in each word line group of the memory block, store the result of the word line test for each word line group of the memory block as the group defect information in the group defect information storage unit, update an access record on the memory block, and perform the requested operation on the memory block.

7. The semiconductor memory device of claim 6, wherein, when at least one defective word line is included in each word line group of the memory block, the control logic determines the corresponding word line group as a defective word line group, and
wherein, when all word lines included in the corresponding word line group are normal word lines, the control logic determines the corresponding word line group as a normal word line group.

8. The semiconductor memory device of claim 5, wherein the plurality of word line groups include word lines having the same number.

9. An operating method for a semiconductor memory device including a plurality of memory blocks, the operating method comprising:
receiving a command for any one memory block among the plurality of memory blocks;
determining whether to perform a defect test on the memory block;
performing the defect test based on a determination; and
performing an operation corresponding to the received command on the memory block.

10. The operating method of claim 9, wherein whether to perform the defect test is determined based on whether the memory block is first accessed,
wherein the command includes any one of a program command, a read command, and an erase command, and the operation corresponding to the received command includes any one of a program operation, a read operation, and an erase operation.

11. The operating method of claim 10, wherein whether the memory block is first accessed is determined based on an access record for the memory block.

12. The operating method of claim 11, wherein the performing of the defect test based on the determination, includes:
performing a word line test on at least one of a plurality of word lines included in the memory block when the memory block is first accessed;
storing word line defect information of the memory block; and
updating the access record for the memory block.

13. The operating method of claim 12, wherein the performing of the word line test on at least one of the plurality of word lines included in the memory block includes:
performing an erase operation on all memory cells in the memory block; and
detecting defective word lines in the memory block in the erase operation.

14. The operating method of claim 12, wherein the performing of the word line test on at least one of the plurality of word lines included in the memory block includes:
performing a program operation on all memory cells in the memory block; and
detecting defective word lines in the memory block in the program operation.

15. The operating method of claim 14, wherein the performing of the word line test on at least one of the plurality of word lines included in the memory block further includes:
performing a data read operation on all memory cells in the memory block; and
detecting defective word lines in the memory block in the data read process.

16. The operating method of claim 14, the performing of the word line test on at least one of the plurality of word lines included in the memory block further includes:
after detecting the defective word lines, performing an erase operation on the memory block.

17. The operating method of claim 11, wherein the performing of the defect test, based on the determination, includes:
performing a word line group test on at least one of a plurality of word line groups included in the memory block when the memory block is first accessed;
storing word line group defect information of the memory block; and
updating the access record on the memory block.

18. The operating method of claim 17, wherein the performing of the word line group test on at least one of the plurality of word line groups included in the memory block includes:
grouping all word lines in the memory block into the plurality of word line groups; and
testing each of the plurality of word line groups to determine whether the corresponding word line group includes at least one defective word line.

19. The operating method of claim 18, wherein, in the testing of each of the plurality of word line groups, a word line test is performed on all word lines in the corresponding word line group,
wherein, when at least one word line is determined as a defective word line, the corresponding word line group is determined as a defective word line group, and
wherein, when all of the word lines are determined as normal word lines, the corresponding word line group is determined as a normal word line group.

20. A controller that controls a semiconductor memory device including a memory cell array configured with a plurality of memory blocks and receives a host command and a logic address corresponding thereto from a host, the controller comprising:
a random access memory (RAM) configured to include a map table;
an address managing unit configured to convert the logical address into a physical address with reference to the map table; and
a test determining unit configured to determine whether the semiconductor memory device is to be tested, based on the physical address.

21. The controller of claim 20, wherein, when it is determined that the semiconductor memory device is to be tested, the test determining unit generates a test command and transmits the test command to the semiconductor memory device, and transmits the host command to the semiconductor memory device after the test command is generated.

22. The controller of claim 20, wherein the test determining unit includes:
a command queue configured to store the host command;
a block access information storage unit configured to store access records of the plurality of memory blocks included in the semiconductor memory device;
a command control unit configured to determine whether the semiconductor memory device is to be tested, based on an access record of a memory block corresponding to the physical address; and
a test command generating unit configured to generate a test command for testing the semiconductor memory device, based on a determination of the command control unit.

23. The controller of claim 22, wherein, when the memory block corresponding to the physical address is first accessed, the command control unit controls the test command generating unit to generate the test command and transmit the test command to the semiconductor memory device.

24. The controller of claim 23, wherein, after the test command is transmitted, the command control unit controls the command queue to transmit the stored host command to the semiconductor memory device.

25. The controller of claim 22, wherein, when the memory block corresponding to the physical address has already been accessed, the command control unit controls the command queue to transmit the stored host command to the semiconductor memory device without generating the test command by the test command generating unit.

26. The controller of claim 20, wherein the RAM is used as an operation memory, and arbitrarily stores write data received from the host or read data received from the semiconductor memory device.
